(19) United States
(12) Patent Application Publication
(10) Pub. No.: US 2026/0178803 A1
(43) Pub. Date: Jun. 25, 2026

(54) Attention-Based Learning For Fluid State Interpolation and Editing in a Time-Continuous Framework

(71) Applicant: Autodesk, Inc., San Francisco, CA (US)

(72) Inventor: Bruno Roy, Longueuil (CA)

(73) Assignee: Autodesk, Inc., San Francisco, CA (US)

(21) Appl. No.: 19/429,570

(22) Filed: Dec. 22, 2025

Related U.S. Application Data
(60) Provisional application No. 63/738,337, filed on Dec. 23, 2024.

(51) Int. Cl. G06F 30/28

(52) U.S. Cl. CPC G06F 30/28

(57) ABSTRACT

A method and system provide the ability to interpolate fluids. At least two keyframes are produced, for a physics based fluid simulation. The keyframes are within a continuous-time framework and separated by a defined interval. Each keyframe includes one or more fluid elements having a corresponding state. Data is prepared utilizing a pre-trained transformer-based network by: (i) handling a tokenization process in a physics-adapted context; and (ii) generating temporal embeddings for states of the one or more fluid elements. Based on the prepared data, a time-continuous density is prepared for substeps between the two keyframes using a density network.

### CROSS-REFERENCE TO RELATED APPLICATIONS

This application claims the benefit under 35 U.S.C. Section 119 (e) of the following co-pending and commonly-assigned U.S. provisional patent application(s), which is/are incorporated by reference herein:

Provisional Application Ser. No. 63/738,337, filed on Dec. 23, 2024, with inventor(s) Bruno Roy, entitled “Attention-Based Learning For Fluid State Interpolation and Editing in a Time-Continuous Framework,” attorneys' docket number 30566.0637USP1.

### BACKGROUND OF THE INVENTION

### 1. Field of the Invention

The present invention relates generally to fluid simulation, and in particular, to a method, apparatus, system, and article of manufacture for de-linearizing the simulation process for fluids.

### 2. Description of the Related Art

(Note: This application references a number of different publications as indicated throughout the specification by author names followed by a year of publication enclosed in brackets, e.g., [Abcd 20XX]. A list of these different publications ordered according to these names and years can be found below in the section entitled “References.” Each of these publications is incorporated by reference herein.)

Numerical fluids are complex phenomena and challenging to simulate realistically. In this regard, “numerical fluids” refers to computational fluid dynamics (CFD), a field using numerical analysis and algorithms to solve complex fluid flow problems (like air/water movement, heat transfer) that are too difficult for analytical solutions by discretizing equations (like Navier-Stokes) into grids and approximating derivatives using methods like finite differences ro volumes for computer simulation. By using traditional solvers, these complex phenomena are very difficult to edit and control. Thus, it is desirable to easily and efficiently edit and control complex fluid flow problems. To better understand these problems, a description of fluid dynamics and prior art approaches and solutions may be useful.

As the era of generative AI advances, there has been a growing interest in editing within the latent space, posing a significant challenge in delivering controllable data-driven capabilities. Among many other areas in computer graphics, physics-based animation remains particularly challenging to edit as it relies on complex physics rules and principles that need to be satisfied for realism. Another challenge posed by these physics-based phenomena, particularly within the VFX (visual effects) industry is the need to adapt these principles to align with artistic direction, as observed in animation films. Striking a balance between realism and controllability poses difficulty in providing tools for editing natural phenomena such as fluids. For several decades, numerous researchers have endeavored to enhance the controllability and flexibility of fluid editing-spanning from local editing of keyframes [Pan 2013] to flow-based methods [Sato 2018]. While the latter showed promise in terms of controllability, some explored optical flow-based approaches to interpolate Eulerian [Thuerey 2016] and particle-based fluids [Roy 2021] as novel means of creating and editing such natural phenomena. Although also promising, these flow-based approaches remained highly dependent on numerical solvers, rendering them still fairly computationally expensive.

More recently, data-driven methods have emerged to simulate and control fluids at a reduced cost. Introduced to computer graphics approximately a decade ago, [Ladick\grave{y} 2015] proposed a novel approach to computing particle acceleration using a regression forest. Subsequently, a significant advancement was made by utilizing LSTM-based (long short-term memory based) methods [Wiewel 2019] to handle and compute pressure changes as sequential data. Similarly, other works were introduced to address the pressure projection step using CNNs (convolutional neural networks) [Tompson 2017; Yang 2016]. Techniques were also proposed to synthesize smoke from pre-computed patches [Chu and Thuerey 2017], generate super-resolution flows using GANs (generative adversarial networks) [Xie et al. 2018], and enhance diffusion behavior and liquid splashes [Um et al. 2018]. In recent years, methods have been introduced to improve the apparent resolution of smoke [Bai et al. 2020] and particle-based liquids [Roy et al. 2021].

Further related works include physics-informed ML (machine-learning) using prior knowledge during learning stages ([Lorsung 2024; and He 2016]), to time continuous learning using vector fields to update the model parameters in a time-continuous framework ([Deleu 2022]).

Although an objective remains to enhance the controllability of fluid editing, embodiments of the invention may share similarities with that of [Thuerey 2016] and [Roy et al. 2021] as embodiments may aim to interpolate fluids in a data-driven manner using the advection scheme of Eulerian simulations.

### SUMMARY OF THE INVENTION

Embodiments of the invention introduce a transformer-based approach for continuous fluid interpolation (referred to herein as the FLUIDSFORMER™ application), that provides one or more of the following contributions:
adapts a transformer-based approach for fluid interpolation;
combines the capabilities of physics-informed ML and residual connections in residual neural networks (RNNs) to analytically predict the physical properties of the fluid state;
uses time-continuous learning to evaluate substeps and offer a discretization-free interpolation; and
demonstrates various applications such as: (1) substep interpolation, (2) constructive solid geometry (CSG)-inspired operation for generation/edition, and (3) generating simulation variants using a tree-based structure.

### BRIEF DESCRIPTION OF THE DRAWINGS

Referring now to the drawings in which like reference numbers represent corresponding parts throughout:

FIG. 1 illustrates an overview of the fluid simulation interpolation in accordance with one or more embodiments of the invention;

FIG. 2 illustrates an overview of the transformer based approach for continuous fluid interpolation in accordance with one or more embodiments of the invention;

FIG. 3 illustrates an exemplary generation of new animations in accordance with one or more embodiments of the invention;

FIG. 4 illustrates the combination of the attention-based learning for fluid state interpolation with an explicit solver to generate viscosity variations for liquids in accordance with one or more embodiments of the invention;

FIG. 5 illustrates the density error reduction when using physics-informed learning in accordance with one or more embodiments of the invention;

FIG. 6 illustrates the logical flow for interpolating fluids in accordance with one or more embodiments of the invention;

FIG. 7 is an exemplary hardware and software environment used to implement one or more embodiments of the invention; and

FIG. 8 schematically illustrates a typical distributed/cloud-based computer system in accordance with one or more embodiments of the invention.

### DETAILED DESCRIPTION OF THE INVENTION

In the following description, reference is made to the accompanying drawings which form a part hereof, and which is shown, by way of illustration, several embodiments of the present invention. It is understood that other embodiments may be utilized and structural changes may be made without departing from the scope of the present invention.

### Overview

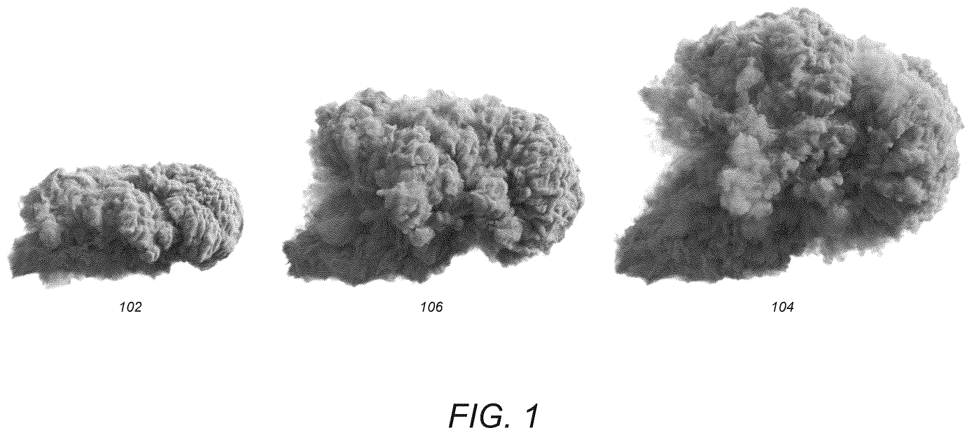

Embodiments of the invention provide for attention-based learning for fluid state interpolation and editing in a time-continuous framework. FIG. 1 illustrates an overview of the fluid simulation interpolation in accordance with one or more embodiments of the invention. Given input keyframes, substeps of a fluid simulation are interpolated resulting in a smooth and realistic animation. More specifically, FIG. 1 illustrates input reference keyframes 102 at time t−0, an and input reference keyframe 104 at time t=1, with the interpolated frame 106 at t−0.5 (with the interpolated frame 106 resulting in a smooth/realistic animation/transition from frame 102 to frame 104).

### Methodology

Although transformer-based networks have been primarily introduced for natural language processing (NLP) and text generation, they offer interesting properties for sequential data in general. Embodiments of the invention leverage an attention-based architecture within a continuous-time framework to learn and interpolate simulation properties per frame in an approximate analytical manner. In the following sections, the details describe the invention spanning from data preparation to network architecture and training using a transformer-based encoder-decoder network. A few concrete use cases are highlighted to introduce novel ways of generating and editing fluids.

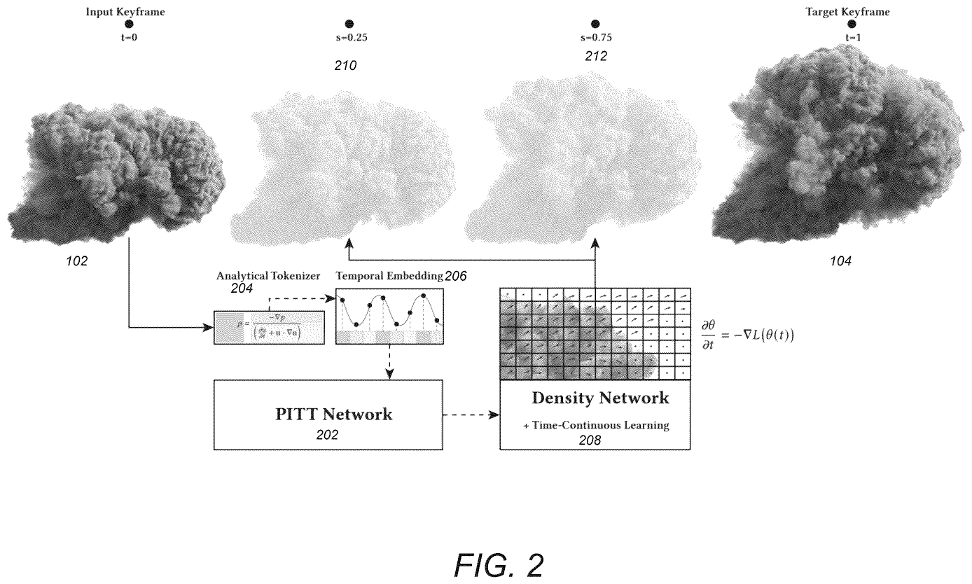

FIG. 2 illustrates an overview of the transformer based approach for continuous fluid interpolation in accordance with one or more embodiments of the invention. A convention Eulerian solver is used to produce keyframes (i.e., input keyframes 102 and 104) along with their respective volumetric properties, using a large timestep (e.g., from t=0 to t=1). Most of the Physics-Informed Transformer Token (PITT) network 202 is leveraged to tokenize (e.g., via an analytical tokenizer 204) and embed (e.g., via temporal embedding 206) the partial differential equations (PDEs) needed to compute the density at any given time between the reference frames 102 and 104. The density network 208 predicts the advected densities at substeps 210-212 (e.g., s=[0.25, 0.75]).

### Data Preparation

The data preparation is divided into two main steps: (1) generating the temporal embeddings 206 for the fluid element's states and (2) handling the tokenization process 204 in a physics-adapted context.

### Physics-Adapted Tokenization 204

The tokenization process 204 is performed by parsing and splitting the Navier-Stokes equation into components (see Eq. 1)—the viscosity term may be intentionally omitted to simplify the related operations.

$$ρ ( \frac{\partial u}{\partial t} + u \cdot ∇ u ) = - ∇ p \qquad ( 1 )$$

### Temporal Embedding 206

The latent embedding of the advection part of the governing equation may be learned using standard multi-head self-attention blocks from PITT architecture 202 [Lorsung et al. 2024]. That way, a model of embodiments of the invention is capable of learning to interpolate physics properties analytically (e.g., densities p). As the equilibrium equation (i.e., ∇·u=0) is not considered, the volume preservation part may be handled by simply penalizing (in a loss function) the solutions diverging too much from the reference.

### Network Architecture

The network architecture of embodiments of the invention is composed of two stacked networks: (1) the pre-trained PITT network 202 (transformer-based network) for solving the governing partial differential equation of the fluid dynamics and (2) the density network 208 (residual neural network [RNN]) to learn and infer/predict the time-continuous fluid properties (e.g., density) for the substeps 210-212 between the input keyframes 102-104. Embodiments use an 18-layer architecture for a residual neural network as it gives a decent performance (i.e., training/inference speed and accuracy) while reducing the requirement for an enormous dataset.

### Training and Dataset

The density network 208 is trained on normalized data [−1, 1] outputted from the PITT network 202. During training, each simulation scenario is processed through the PITT network 202 to generate the latent embedding of the non-viscous governing equation and provides an analytically-driven approximation to the density network 208 to predict the correct density in space and time. To update the parameters, a Huber loss function L_{δ} may be utilized to minimize a single term considering the possible outliers (with some regularization term): the difference in density between the ground truth ρ and the prediction ρ.

$${L}_{δ} ( ρ , \hat{ρ} ) = \{ \begin{matrix}\frac{1}{2} {( ρ - \hat{ρ} )}^{2} & \vert ρ - \hat{ρ} \vert \leq δ \\ δ \vert ρ - \hat{ρ} \vert - \frac{1}{2} {δ}^{2} & otherwise .\end{matrix} \qquad ( 2 )$$

As the reference density is advected using the divergence-free velocity field, embodiments already have the volume preservation law.

The hyperparameters of the model have been validated and tweaked using a 2D dataset of laminar and turbulent flows generated with the OpenFOAM application [Jasak 2009]. Volumetric data was generated from Eulerian simulations using a visual programming environment (e.g., the BIFROST™ visual programming environment inside of AUTODESK™ MAYA™) (e.g., for testing). The volumetric data points are constituted of a position (center of the cell), a velocity, and a density. The volumetric dataset is composed of 1000 (800 for training, 100 for validation, and 100 for testing) smoke inflow and emission simulations of 50 frames in length, without and with a single obstacle placed at random locations. As for most RNN architectures, a significant amount of data may be needed to properly generalize without dissipating the small-scale details in the simulation (e.g., second-order vorticity).

### Continuous-Time Learning

Similarly to [Chen et al. 2024], embodiments of the invention may provide an architecture that uses a continuous-time multi-head attention module to transform time-varying sequence relationships into vectors of queries Q, keys K, and values V. As opposed to [Chen et al. 2024] and inspired by [Deleu et al. 2022], the learning algorithm may be formulated to follow the input velocity during training-allowing the model (of embodiments of the invention) to converge faster and to reflect the analytical framework as discussed above. The updated gradients are then used to update the parameters defining the fluid state. In other words, embodiments of the invention may train the model to evaluate the density based on the advection term and the velocities of the governing equation of the input system. An inherent advantage of the analytically-driven approach (of embodiments of the invention) is that the inference part can be performed discretization-free. In other words, an inherent advantage of analytically learning density advection is the flexibility to dynamically choose the discretization during the inference stage as required. Essentially, by employing the pre-trained PITT network 202, embodiments of the invention evenly divide the time interval between two keyframes 102-104 into a specified number of substeps S 210-212. Subsequently, the density is evaluated at these time points 210-212 while considering the initial conditions. The density ρ is computed at location x by advecting the previous density with respect to the input velocity.

### Various Applications

### Eulerian Fluids Interpolation

One goal with this approach is to propose a continuous-time transformer model capable of learning the underlying dynamics of fluid systems for interpolation purposes. The idea behind interpolating fluids is to generate a visually appealing and temporally smooth animation using only a few keyframes 102-104 at large timesteps. Interpolation methods of embodiments of the invention will fill in between similarly to simulating the substeps between the provided reference keyframes 102-104 (as shown in FIG. 1 and FIG. 2).

### Generating Using Variants

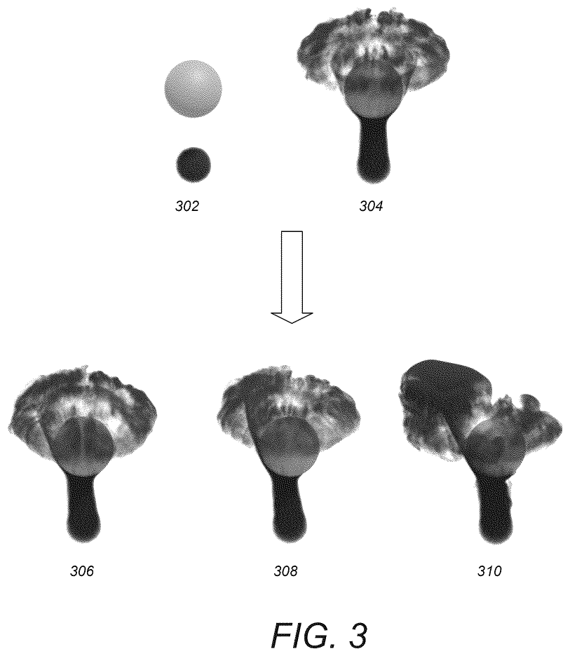

In one use case, embodiments of the invention take advantage of the generated tree structure to combine keyframes using Boolean operations such as addition, subtraction, and intersection (e.g., CSG) operations. Using the volumetric data (i.e., properly stored in grid cells), multiple keyframes can be mixed into a single target to produce a completely new animation. FIG. 3 illustrates an exemplary generation of new animations in accordance with one or more embodiments of the invention. As illustrated input keyframes 302-304 are mixed into a single target to generate new animations 306-310. In other words, embodiments of the invention are capable of generating new animations 306-310 by mixing multiple keyframes 302-304 into a single target.

### Tree-Based Variants

Embodiments of the invention are also capable of generating tree-based variants. For each frame, multiple probable solutions are output using top-k sampling along with Diverse Beam Search (DBS) (a decoding algorithm) on the decoder side to encourage diversity in the generated sequences. From this set of solutions, a tree structure is built that allows embodiments of the invention to branch out at any node to produce variants of a single simulation while preserving the initial conditions. Experiments combine this approach with an explicit solver for liquid simulations. As opposed to other presented use cases, the approach has been tested to interpolate between various viscosity states.

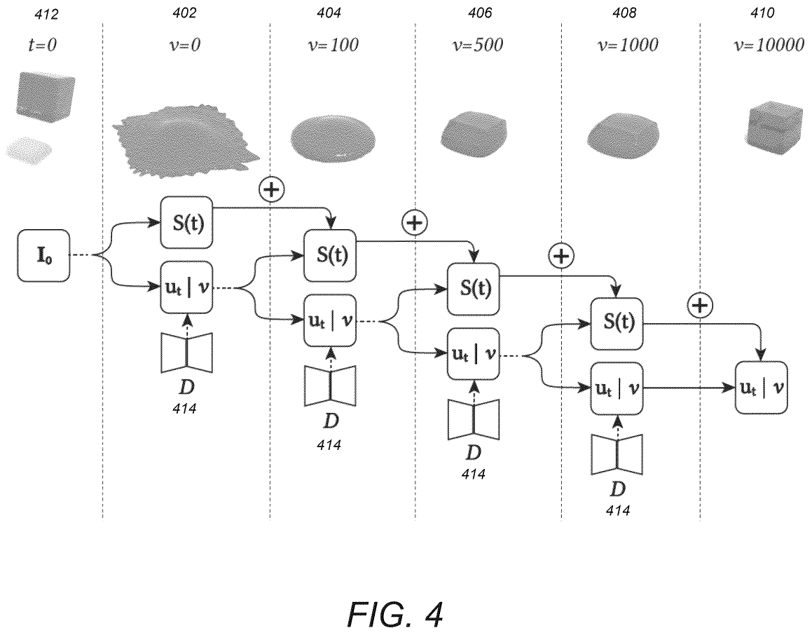

FIG. 4 illustrates the combination of the attention-based learning for fluid state interpolation with an explicit solver to generate viscosity variations for liquids in accordance with one or more embodiments of the invention. As illustrated, The fluid state interpolation methodology is used to produce five (5) variations 402-410 of the same simulation but using different viscosity values v (0 being the less viscous and 10000 the most). Starting with the same initial conditions I₀ at 412, a new variation of the current state of the velocity is branched by predicting the next sequence of velocities according to a certain viscosity threshold (e.g., v∈{0, 100, 500, 1000, 10000}). To learn and generate these sequences based on the current state, a viscosity network D 414 was trained (i.e., including the viscosity term in the PITT embedding as input to a residual neural network) to match similarities between fluid characteristics (e.g., viscosity) and their corresponding velocities. Between each reference keyframe generated by the explicit solver, the network D 414 interpolates viscosities 402-410 to generate the substeps which are guided by the computed velocity field.

### Performance

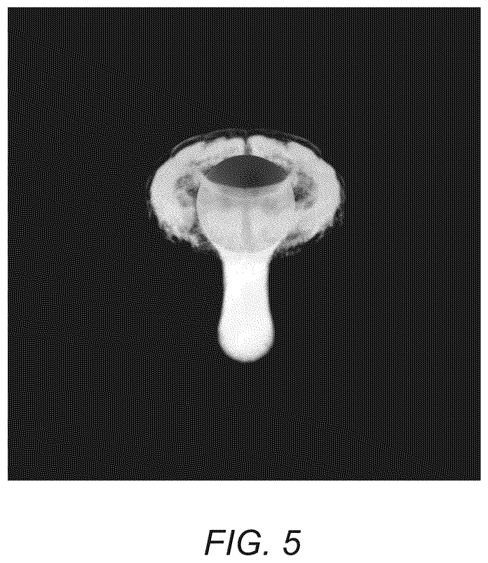

One advantage of using physics-informed learning is that the requirement for data during training is reduced significantly (Table 1). In this regard, Table 1 illustrates the average computation times per epoch performed on a single GPU. The accuracy is compared to an OpenFOAM™ CFD toolbox ground truth. Training and inference accuracy are respectively computed using the validation and test sets. Also, the training time is decreased by a factor of 5 for more complex scenarios. As shown in FIG. 5, the density error is very low (low: white and high: black) when compared to the ground truth (generated using the OpenFOAM™ CFD toolbox).

TABLE 1

| | Training | | Inference | |
|---|---|---|---|---|
| Network | Time (mins) | Accuracy | Time (ms) | Accuracy |
| Physics-Informed | 15 ± 1.2 | 96.4% | 207 ± 17 | 94.3% |
| Density (RNN) | 52 ± 3.6 | 91.2% | 307 ± 12 | 93.6% |
| Deep Neural | 34 ± 2.8 | 84.7% | 436 ± 34 | 86.1% |

### Logical Flow

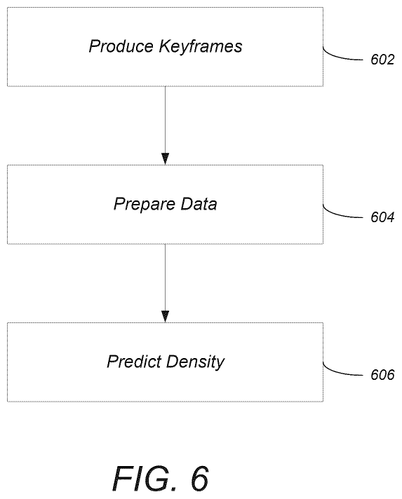

FIG. 6 illustrates the logical flow for interpolating fluids in accordance with one or more embodiments of the invention.

At step 602, at least two keyframes (along with respective volumetric properties) are produced for a physics based fluid simulation. The keyframes are within a continuous-time framework and separated by a defined interval. Further, each keyframe consists of one or more fluid elements having a corresponding state. The keyframes may be produced using a Eulerian solver.

At step 604, data is prepared utilizing a pre-trained transformer-based network. The data preparation handles a tokenization process in a physics-adapted context. Further, the data preparation process generates temporal embeddings for states of the one or more fluid elements.

Such tokenization process may include parsing and splitting the Navier-Stokes equation into components where a viscosity term is omitted. Further, an advection part of the Navier-Stokes equation may be learned using multi-head self-attention blocks from the pre-trained transformer-based network. In addition, a volume preservation part of the temporal embedding may be handled by penalizing, in a loss function, solutions that diverge beyond a threshold from a reference. The advection part may transform time-varying sequence relationships into vectors (of queries, keys, and values) to output a continuous dynamic flow evolving through the data.

In addition to the above, during the training of the pre-trained transformer-based network, an input velocity may be followed.

Further, the pre-trained transformer-based network may be a Physics-Informed Transformer Token (PITT) network that is utilized to solve a partial differential equation of fluid dynamics.

At step 606, based on the prepared data, a time-continuous density for substeps between the two keyframes are predicted using a density network. The density network may consist of and/or be a part of a residual neural network (RNN) with multiple layers.

The preparation of the data may further include the normalization of the prepared data. In this regard, the density network may be trained on the normalized prepared data output from the pre-trained transformed-based network. During training, each simulation scenario may be processed through the pre-trained transformer-based network to generate a latent embedding of a non-viscous governing equation and provide an analytically-driven approximation to the density network to predict a correct density in space and time.

Further to the above, step 606 may further include employing the pre-trained transformer-based network to evenly divide the time interval between the at least two keyframes into a specified number of the substeps S. Thereafter, the time-continuous density may be evaluated at time points of the substeps while considering the respective volumetric properties. The time-continuous density ρ is computed at a location x by advecting a previous density with respect to an input velocity.

Steps 602-606 may further include generating using variants. For example, a tree structure may be generated to combine the at least two keyframes using Boolean operations. The respective volumetric properties are stored in grid cells of the tree structure. The stored respective volumetric properties are then used to mix the at least two keyframes into a single target and produce a new animation.

Alternatively (or in addition), an application of embodiments of the invention may utilize tree-based variants. In such embodiments, for each of the at least two keyframes, multiple probable solutions are output using top-k sampling along with a Diverse Beam Search on a decoder side. From the multiple probable solutions, a tree structure is built that enables branching out at any node to produce a variant of a single simulation while preserving initial conditions.

### Hardware Environment

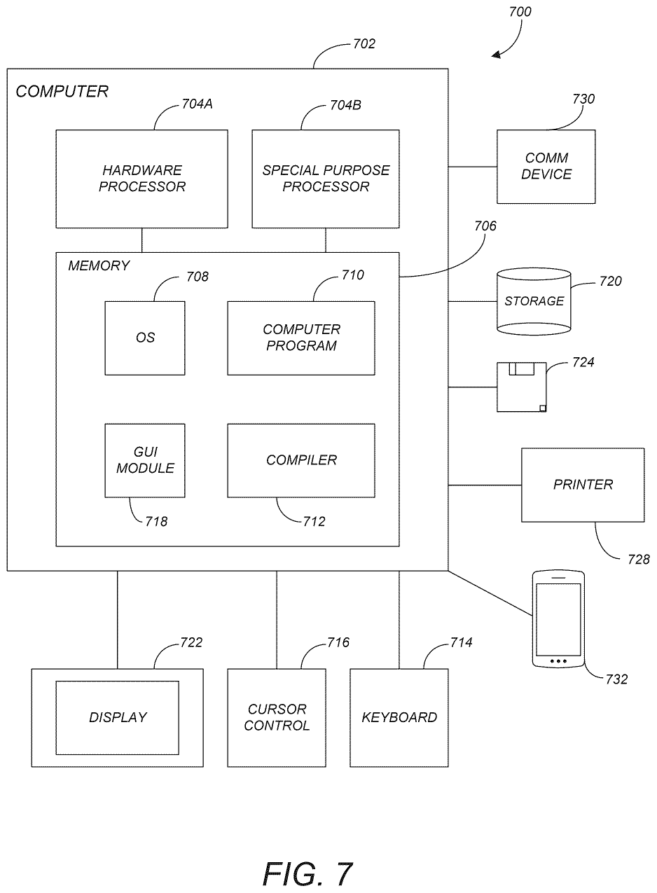

FIG. 7 is an exemplary hardware and software environment 700 (referred to as a computer-implemented system and/or computer-implemented method) used to implement one or more embodiments of the invention. The hardware and software environment includes a computer 702 and may include peripherals. Computer 702 may be a user/client computer, server computer, or may be a database computer. The computer 702 comprises a hardware processor 704A and/or a special purpose hardware processor 704B (hereinafter alternatively collectively referred to as processor 704) and a memory 706, such as random access memory (RAM). The computer 702 may be coupled to, and/or integrated with, other devices, including input/output (I/O) devices such as a keyboard 714, a cursor control device 716 (e.g., a mouse, a pointing device, pen and tablet, touch screen, multi-touch device, etc.) and a printer 728. In one or more embodiments, computer 702 may be coupled to, or may comprise, a portable or media viewing/listening device 732 (e.g., an MP3 player, IPOD, NOOK, portable digital video player, cellular device, personal digital assistant, etc.). In yet another embodiment, the computer 702 may comprise a multi-touch device, mobile phone, gaming system, internet enabled television, television set top box, or other internet enabled device executing on various platforms and operating systems.

In one embodiment, the computer 702 operates by the hardware processor 704A performing instructions defined by the computer program 710 (e.g., a computer-aided design [CAD] application) under control of an operating system 708. The computer program 710 and/or the operating system 708 may be stored in the memory 706 and may interface with the user and/or other devices to accept input and commands and, based on such input and commands and the instructions defined by the computer program 710 and operating system 708, to provide output and results.

Output/results may be presented on the display 722 or provided to another device for presentation or further processing or action. In one embodiment, the display 722 comprises a liquid crystal display (LCD) having a plurality of separately addressable liquid crystals. Alternatively, the display 722 may comprise a light emitting diode (LED) display having clusters of red, green and blue diodes driven together to form full-color pixels. Each liquid crystal or pixel of the display 722 changes to an opaque or translucent state to form a part of the image on the display in response to the data or information generated by the processor 704 from the application of the instructions of the computer program 710 and/or operating system 708 to the input and commands. The image may be provided through a graphical user interface (GUI) module 718. Although the GUI module 718 is depicted as a separate module, the instructions performing the GUI functions can be resident or distributed in the operating system 708, the computer program 710, or implemented with special purpose memory and processors.

In one or more embodiments, the display 722 is integrated with/into the computer 702 and comprises a multi-touch device having a touch sensing surface (e.g., track pod, touch screen, smartwatch, smartglasses, smartphones, laptop or non-laptop personal mobile computing devices) with the ability to recognize the presence of two or more points of contact with the surface. Examples of multi-touch devices include mobile devices (e.g., IPHONE, ANDROID devices, WINDOWS phones, GOOGLE PIXEL devices, NEXUS S, etc.), tablet computers (e.g., IPAD, HP TOUCHPAD, SURFACE Devices, etc.), portable/handheld game/music/video player/console devices (e.g., IPOD TOUCH, MP3 players, NINTENDO SWITCH, PLAYSTATION PORTABLE, etc.), touch tables, and walls (e.g., where an image is projected through acrylic and/or glass, and the image is then backlit with LEDs).

Some or all of the operations performed by the computer 702 according to the computer program 710 instructions may be implemented in a special purpose processor 704B. In this embodiment, some or all of the computer program 710 instructions may be implemented via firmware instructions stored in a read only memory (ROM), a programmable read only memory (PROM) or flash memory within the special purpose processor 704B or in memory 706. The special purpose processor 704B may also be hardwired through circuit design to perform some or all of the operations to implement the present invention. Further, the special purpose processor 704B may be a hybrid processor, which includes dedicated circuitry for performing a subset of functions, and other circuits for performing more general functions such as responding to computer program 710 instructions. In one embodiment, the special purpose processor 704B is an application specific integrated circuit (ASIC).

The computer 702 may also implement a compiler 712 that allows an application or computer program 710 written in a programming language such as C, C++, Assembly, SQL, PYTHON, PROLOG, MATLAB, RUBY, RAILS, HASKELL, or other language to be translated into processor 704 readable code. Alternatively, the compiler 712 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 710 accesses and manipulates data accepted from I/O devices and stored in the memory 706 of the computer 702 using the relationships and logic that were generated using the compiler 712.

The computer 702 also optionally comprises an external communication device such as a modem, satellite link, Ethernet card, or other device for accepting input from, and providing output to, other computers 702.

In one embodiment, instructions implementing the operating system 708, the computer program 710, and the compiler 712 are tangibly embodied in a non-transitory computer-readable medium, e.g., data storage device 720, which could include one or more fixed or removable data storage devices, such as a zip drive, floppy disc drive 724, hard drive, CD-ROM drive, tape drive, etc. Further, the operating system 708 and the computer program 710 are comprised of computer program 710 instructions which, when accessed, read and executed by the computer 702, cause the computer 702 to perform the steps necessary to implement and/or use the present invention or to load the program of instructions into a memory 706, thus creating a special purpose data structure causing the computer 702 to operate as a specially programmed computer executing the method steps described herein. Computer program 710 and/or operating instructions may also be tangibly embodied in memory 706 and/or data communications devices 730, thereby making a computer program product or article of manufacture according to the invention. As such, the terms “article of manufacture,” “program storage device,” and “computer program product,” as used herein, are intended to encompass a computer program accessible from any computer readable device or media.

Of course, those skilled in the art will recognize that any combination of the above components, or any number of different components, peripherals, and other devices, may be used with the computer 702.

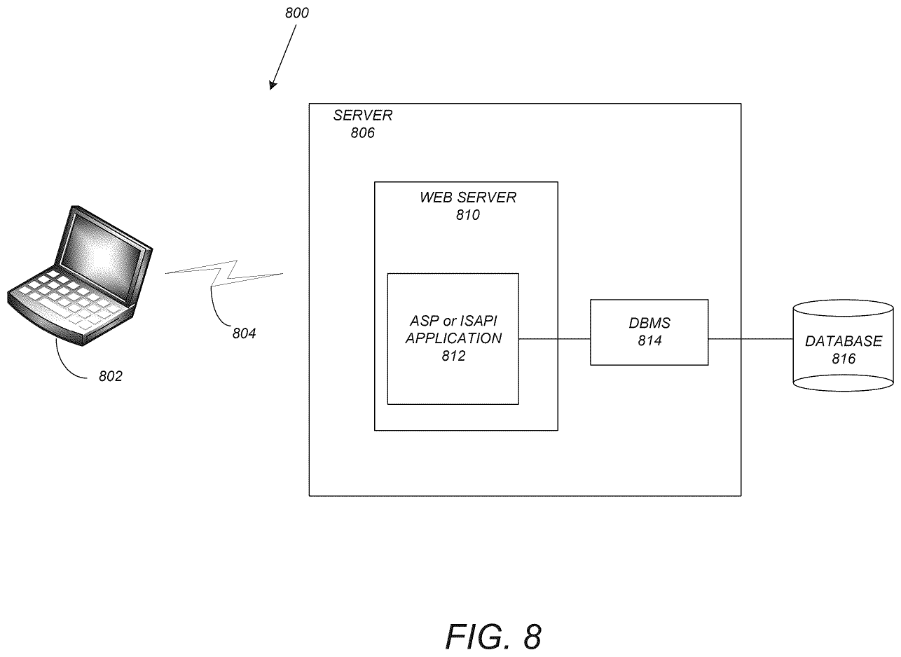

FIG. 8 schematically illustrates a typical distributed/cloud-based computer system 800 using a network 804 to connect client computers 802 to server computers 806. A typical combination of resources may include a network 804 comprising the Internet, LANs (local area networks), WANs (wide area networks), SNA (systems network architecture) networks, or the like, clients 802 that are personal computers or workstations (as set forth in FIG. 7), and servers 806 that are personal computers, workstations, minicomputers, or mainframes (as set forth in FIG. 7). However, it may be noted that different networks such as a cellular network (e.g., GSM [global system for mobile communications] or otherwise), a satellite based network, or any other type of network may be used to connect clients 802 and servers 806 in accordance with embodiments of the invention.

A network 804 such as the Internet connects clients 802 to server computers 806. Network 804 may utilize ethernet, coaxial cable, wireless communications, radio frequency (RF), etc. to connect and provide the communication between clients 802 and servers 806. Further, in a cloud-based computing system, resources (e.g., storage, processors, applications, memory, infrastructure, etc.) in clients 802 and server computers 806 may be shared by clients 802, server computers 806, and users across one or more networks. Resources may be shared by multiple users and can be dynamically reallocated per demand. In this regard, cloud computing may be referred to as a model for enabling access to a shared pool of configurable computing resources.

Clients 802 may execute a client application or web browser and communicate with server computers 806 executing web servers 810. Such a web browser is typically a program such as MICROSOFT INTERNET EXPLORER/EDGE, MOZILLA FIREFOX, OPERA, APPLE SAFARI, GOOGLE CHROME, etc. Further, the software executing on clients 802 may be downloaded from server computer 806 to client computers 802 and installed as a plug-in or ACTIVEX control of a web browser. Accordingly, clients 802 may utilize ACTIVEX components/component object model (COM) or distributed COM (DCOM) components to provide a user interface on a display of client 802. The web server 810 is typically a program such as MICROSOFT'S INTERNET INFORMATION SERVER.

Web server 810 may host an Active Server Page (ASP) or Internet Server Application Programming Interface (ISAPI) application 812, which may be executing scripts. The scripts invoke objects that execute business logic (referred to as business objects). The business objects then manipulate data in database 816 through a database management system (DBMS) 814. Alternatively, database 816 may be part of, or connected directly to, client 802 instead of communicating/obtaining the information from database 816 across network 804. When a developer encapsulates the business functionality into objects, the system may be referred to as a component object model (COM) system. Accordingly, the scripts executing on web server 810 (and/or application 812) invoke COM objects that implement the business logic. Further, server 806 may utilize MICROSOFT'S TRANSACTION SERVER (MTS) to access required data stored in database 816 via an interface such as ADO (Active Data Objects), OLE DB (Object Linking and Embedding DataBase), or ODBC (Open DataBase Connectivity).

Generally, these components 800-816 all comprise logic and/or data that is embodied in/or retrievable from device, medium, signal, or carrier, e.g., a data storage device, a data communications device, a remote computer or device coupled to the computer via a network or via another data communications device, etc. Moreover, this logic and/or data, when read, executed, and/or interpreted, results in the steps necessary to implement and/or use the present invention being performed.

Although the terms “user computer”, “client computer”, and/or “server computer” are referred to herein, it is understood that such computers 802 and 806 may be interchangeable and may further include thin client devices with limited or full processing capabilities, portable devices such as cell phones, notebook computers, pocket computers, multi-touch devices, and/or any other devices with suitable processing, communication, and input/output capability.

Of course, those skilled in the art will recognize that any combination of the above components, or any number of different components, peripherals, and other devices, may be used with computers 802 and 806. Embodiments of the invention are implemented as a software/CAD application on a client 802 or server computer 806. Further, as described above, the client 802 or server computer 806 may comprise a thin client device or a portable device that has a multi-touch-based display.

### CONCLUSION

This concludes the description of the preferred embodiment of the invention. The following describes some alternative embodiments for accomplishing the present invention. For example, any type of computer, such as a mainframe, minicomputer, or personal computer, or computer configuration, such as a timesharing mainframe, local area network, or standalone personal computer, could be used with the present invention.

Numerical fluids are complex phenomena and challenging to simulate realistically. By using traditional solvers, these phenomena are very difficult to edit and control. Embodiments of the invention enable the de-linearization of the simulation process for fluids. Specifically, embodiments provide a transformer-based approach for fluid interpolation within a continuous-time framework. By combining the capabilities of Physics-Informed Tranformer Networks and a residual neural network (RNN), embodiments of the invention analytically predict the physical properties of the fluid state. This enables the interpolation of substep frames between simulated keyframes, enhancing the temporal smoothness and sharpness of animations. Embodiment of the invention may be utilized for smoke interpolation and liquids. On top of subsep interpolation, embodiments of the invention can produce CSG-inspired operations for generation/edition and generate simulation variants using a tree-based structure.

In view of the above, while embodiments of the invention still rely on a coarse numerical simulation, it introduces novel and less-linear ways of interacting with fluids. Further embodiments utilize the accuracy of employing transformer-based networks like PITT to replace conventional numerical solvers for simulating natural phenomena in visual effects. In addition, by offering a physics-informed way to learn how to interpolate and edit fluid states, embodiments of the invention enable a stochastic and physical way to produce a set of solutions only using a fluid's initial conditions.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

### REFERENCES

[Bai 2020] Kai Bai, Wei Li, Mathieu Desbrun, and Xiaopei Liu. 2020. Dynamic upsampling of smoke through dictionary-based learning. ACM Transactions on Graphics (TOG) 40, 1 (2020), 1-19.
[Chen 2024] Yuqi Chen, Kan Ren, Yansen Wang, Yuchen Fang, Weiwei Sun, and Dongsheng Li. 2024. ContiFormer: Continuous-time transformer for irregular time series modeling. Advances in Neural Information Processing Systems 36 (2024).
[Chu 2017] Mengyu Chu and Nils Thuerey. 2017. Data-driven synthesis of smoke flows with CNN-based feature descriptors. ACM Transactions on Graphics (TOG) 36, 4 (2017), 1-14.
[Deleu 2022] Tristan Deleu, David Kanaa, Leo Feng, Giancarlo Kerg, Yoshua Bengio, Guillaume Lajoie, and Pierre-Luc Bacon. 2022. Continuous-time meta-learning with forward mode differentiation. arXiv preprint arXiv: 2203.01443 (2022).
[He 2016] Kaiming He, Xiangyu Zhang, Shaoqing Ren, and Jian Sun. “Deep residual learning for image recognition.” Proceedings of the IEEE conference on computer vision and pattern recognition, 2016, 770-778.
[Jasak 2009] Hrvoje Jasak. 2009. OpenFOAM: Open source CFD in research and industry. International Journal of Naval Architecture and Ocean Engineering 1, 2 (2009), 89-94.
[Ladick\grave{y} 2015] L'ubor Ladick\grave{y}, SoHyeon Jeong, Barbara Solenthaler, Marc Pollefeys, and Markus Gross. 2015. Data-driven fluid simulations using regression forests. ACM Transactions on Graphics (TOG) 34, 6 (2015), 1-9.
[Lorsung 2024] Cooper Lorsung, Zijie Li, and Amir Barati Farimani. 2024. Physics Informed Token Transformer for Solving Partial Differential Equations. Machine Learning: Science and Technology (2024).
[Pan 2013] Zherong Pan, Jin Huang, Yiying Tong, Changxi Zheng, and Hujun Bao. 2013. Interactive localized liquid motion editing. ACM Transactions on Graphics (TOG) 32, 6 (2013), 1-10.
[Roy 2021] Bruno Roy, Pierre Poulin, and Eric Paquette. 2021. Neural upflow: A scene flow learning approach to increase the apparent resolution of particle-based liquids. Proceedings of the ACM on Computer Graphics and Interactive Techniques 4, 3 (2021), 1-26.
[Sato 2018] Syuhei Sato, Yoshinori Dobashi, and Tomoyuki Nishita. 2018. Editing fluid animation using flow interpolation. ACM Transactions on Graphics (TOG) 37, 5 (2018), 1-12.
[Thuerey 2016] Nils Thuerey. “Interpolations of smoke and liquid simulations.” ACM Transactions on Graphics (TOG) 36.1 (2016): 1-16.
[Tompson 2017] Jonathan Tompson, Kristofer Schlachter, Pablo Sprechmann, and Ken Perlin. 2017. Accelerating eulerian fluid simulation with convolutional networks. In International Conference on Machine Learning. PMLR, 3424-3433.
[Um 2018] Kiwon Um, Xiangyu Hu, and Nils Thuerey. 2018. Liquid splash modeling with neural networks. In Computer Graphics Forum, Vol. 37. Wiley Online Library, 171-182.
[Wiewel 2019] Steffen Wiewel, Moritz Becher, and Nils Thuerey. 2019. Latent space physics: Towards learning the temporal evolution of fluid flow. In Computer graphics forum, Vol. 38. Wiley Online Library, 71-82.
[Xie 2018] You Xie, Erik Franz, Mengyu Chu, and Nils Thuerey. 2018. tempoGAN: A temporally coherent, volumetric GAN for super-resolution fluid flow. ACM Transactions on Graphics (TOG) 37, 4 (2018), 1-15.
[Yang 2016] Cheng Yang, Xubo Yang, and Xiangyun Xiao. 2016. Data-driven projection method in fluid simulation. Computer Animation and Virtual Worlds 27, 3-4 (2016), 415-424.

What is claimed is:

1. A computer-implemented method for interpolating fluids, comprising:
(a) producing, for a physics based fluid simulation, at least two keyframes along with respective volumetric properties, wherein:
(i) the at least two keyframes are within a continuous-time framework and separated by a defined interval; and
(ii) each keyframe comprises one or more fluid elements having a corresponding state;
(b) preparing data utilizing a pre-trained transformer-based network by:
(i) handling a tokenization process in a physics-adapted context;
(ii) generating temporal embeddings for states of the one or more fluid elements; and
(c) predicting, based on the prepared data, a time-continuous density for substeps between the two keyframes using a density network.

2. The computer-implemented method of claim 1, wherein the at least two keyframes are produced using a Eulerian solver.

3. The computer-implemented method of claim 1, wherein the handling the tokenization process comprises:
parsing and splitting the Navier-Stokes equation into components where a viscosity term is omitted.

4. The computer-implemented method of claim 3, further comprising:
learning an advection part of the Navier-Stokes equation using multi-head self-attention blocks from the pre-trained transformer-based network; and
handling a volume preservation part of the temporal embedding by penalizing, in a loss function, solutions that diverge beyond a threshold from a reference.

5. The computer-implemented method of claim 4, wherein the learning the advection part comprises:
transforms time-varying sequence relationships into vectors of queries, keys, and values to output a continuous dynamic flow evolving through the data.

6. The computer-implemented method of claim 4, wherein during training of the pre-trained transformer-based network, an input velocity is followed.

7. The computer-implemented method of claim 1, wherein:
the pre-trained transformer-based network comprises a Physics-Informed Transformer Token (PITT) network; and
the pre-trained transformer based network is utilized to solve a partial differential equation of fluid dynamics.

8. The computer-implemented method of claim 1, wherein:
the density network comprises a residual neural network (RNN) with multiple layers.

9. The computer-implemented method of claim 1, further comprising:
normalizing the prepared data;
training the density network on the normalized prepared data output from the pre-trained transformed-based network, wherein during training:
each simulation scenario is processed through the pre-trained transformer-based network to generate a latent embedding of a non-viscous governing equation and provide an analytically-driven approximation to the density network to predict a correct density in space and time.

10. The computer-implemented method of claim 1, wherein the predicting:
employs the pre-trained transformer-based network to evenly divide the time interval between the at least two keyframes into a specified number of the substeps S;
evaluates the time-continuous density at time points of the substeps while considering the respective volumetric properties, wherein the time-continuous density ρ is computed at a location x by advecting a previous density with respect to an input velocity.

11. The computer-implemented method of claim 1, further comprising:
generating a tree structure to combine the at least two keyframes using Boolean operations;
storing the respective volumetric properties in grid cells of the tree structure; and
using the stored respective volumetric properties to mix the at least two keyframes into a single target and produce a new animation.

12. The computer-implemented method of claim 1, further comprising:
for each of the at least two keyframes, outputting multiple probable solutions using top-k sampling along with a Diverse Beam Search on a decoder side; and
from the multiple probable solutions, building a tree structure that enables branching out at any node to produce a variant of a single simulation while preserving initial conditions.

13. A computer-implemented system for interpolating fluids, comprising:
(a) a computer having a memory;
(b) a processor executing on the computer;
(c) the memory storing a set of instructions, wherein the set of instructions, when executed by the processor cause the processor to perform operations comprising:
(i) producing, for a physics based fluid simulation, at least two keyframes along with respective volumetric properties, wherein:
(1) the at least two keyframes are within a continuous-time framework and separated by a defined interval; and
(2) each keyframe comprises one or more fluid elements having a corresponding state;
(ii) preparing data utilizing a pre-trained transformer-based network by:
(1) handling a tokenization process in a physics-adapted context;
(2) generating temporal embeddings for states of the one or more fluid elements; and
(iii) predicting, based on the prepared data, a time-continuous density for substeps between the two keyframes using a density network.

14. The computer-implemented system of claim 13, wherein the at least two keyframes are produced using a Eulerian solver.

15. The computer-implemented system of claim 13, wherein the operations handling the tokenization process comprises:
parsing and splitting the Navier-Stokes equation into components where a viscosity term is omitted.

16. The computer-implemented system of claim 15, the operations further comprising:
learning an advection part of the Navier-Stokes equation using multi-head self-attention blocks from the pre-trained transformer-based network; and
handling a volume preservation part of the temporal embedding by penalizing, in a loss function, solutions that diverge beyond a threshold from a reference.

17. The computer-implemented system of claim 16, wherein the operations learning the advection part comprise:
transforms time-varying sequence relationships into vectors of queries, keys, and values to output a continuous dynamic flow evolving through the data.

18. The computer-implemented system of claim 16, wherein during training of the pre-trained transformer-based network, an input velocity is followed.

19. The computer-implemented system of claim 13, wherein:
the pre-trained transformer-based network comprises a Physics-Informed Transformer Token (PITT) network; and
the pre-trained transformer based network is utilized to solve a partial differential equation of fluid dynamics.

20. The computer-implemented system of claim 13, wherein:
the density network comprises a residual neural network (RNN) with multiple layers.

21. The computer-implemented system of claim 13, the operations further comprising:
normalizing the prepared data;
training the density network on the normalized prepared data output from the pre-trained transformed-based network, wherein during training:
each simulation scenario is processed through the pre-trained transformer-based network to generate a latent embedding of a non-viscous governing equation and provide an analytically-driven approximation to the density network to predict a correct density in space and time.

22. The computer-implemented system of claim 13, wherein the predicting operations:
employ the pre-trained transformer-based network to evenly divide the time interval between the at least two keyframes into a specified number of the substeps S; and
evaluate the time-continuous density at time points of the substeps while considering the respective volumetric properties, wherein the time-continuous density ρ is computed at a location x by advecting a previous density with respect to an input velocity.

23. The computer-implemented system of claim 13, the operations further comprising:
generating a tree structure to combine the at least two keyframes using Boolean operations;
storing the respective volumetric properties in grid cells of the tree structure; and
using the stored respective volumetric properties to mix the at least two keyframes into a single target and produce a new animation.

24. The computer-implemented system of claim 13, the operations further comprising:
for each of the at least two keyframes, outputting multiple probable solutions using top-k sampling along with a Diverse Beam Search on a decoder side; and
from the multiple probable solutions, building a tree structure that enables branching out at any node to produce a variant of a single simulation while preserving initial conditions.
